(19) United States
(12) Patent Application Publication
(10) Pub. No.: US 2007/0036001 A1
(43) Pub. Date: Feb. 15, 2007

(54) Floating-gate nonvolatile semiconductor memory device

(75) Inventors: Akihiko Kanda, Tokyo (JP); Taku Ogura, Tokyo (JP); Makoto Muneyasu, Tokyo (JP)

Correspondence Address: MCDERMOTT WILL & EMERY LLP, 600 13TH STREET, N.W., WASHINGTON, DC, 20005-3096, US

(73) Assignee: Renesas Technology Corp.

(21) Appl. No.: 11/493,669

(22) Filed: Jul. 27, 2006

(30) Foreign Application Priority Data
Jul. 29, 2005 (JP) 2005-220708

(51) Int. Cl. G11C 16/04; G11C 11/34

(52) U.S. Cl. 365/185.18

(57) ABSTRACT

After data writing is performed by injecting electrons into a floating gate from a semiconductor substrate of a memory cell, the gate voltage is set at −3 V, and the source voltage, the drain voltage and the substrate voltage are set at 0 V, thereby detrapping the electrons trapped in an oxide film during data writing. The gate voltage (−3 V) is set at a negative voltage value that is smaller in absolute value than the gate voltage (−10.5 V) applied during data erasing.

### BACKGROUND OF THE INVENTION

1. Field of the Invention

The present invention relates to a nonvolatile semiconductor memory device. In particular, it relates to a floating-gate nonvolatile semiconductor memory device that is electrically data writable and erasable.

2. Description of the Background Art

In an electrically data writable and erasable floating-gate nonvolatile semiconductor memory device, electrons are injected into a floating gate of a memory cell to achieve data writing, and electrons are drawn from the floating gate to achieve data erasing.

However, in conventional nonvolatile semiconductor memory devices, the charges once trapped in an oxide film OM may be detrapped (released) after completion of the write sequence or erase sequence, thereby changing the threshold voltage of the memory cell.

In Japanese Patent Laid-Open No. 2003-173690, there is disclosed a method of improving the data retention characteristics of a NOR flash memory cell that retains data by accumulating charges in a nitride film formed in a gate insulating film. According to this method, immediately after data writing, a negative voltage that is greater in absolute value than the voltage during data erasing and falls within a range that avoids any FN tunnel current is applied to a control gate, and a voltage of 0 V is applied to each of a silicon substrate, a source and a drain, thereby detrapping the electrons trapped in an electron trap layer of an insulator formed on the gate insulating film into the silicon substrate.

As described above, in conventional nonvolatile semiconductor memory devices, the charges once trapped in an oxide film OM may be detrapped after completion of the write sequence or erase sequence, thereby changing the threshold voltage of the memory cell. As a result there is a problem that the read margin is reduced, and the reliability of the operation is reduced.

### SUMMARY OF THE INVENTION

Thus, a primary object of the present invention is to provide a nonvolatile semiconductor memory device that has an adequate read margin and is improved in operation reliability.

A nonvolatile semiconductor memory device according to the present invention includes: a memory array containing a plurality of memory cells arranged in a plurality of rows and columns, each memory cell having a floating gate and a control gate formed on a semiconductor substrate; and a write/read/erase circuit that performs data writing/reading/erasing on a selected memory cell of the plurality of memory cells, and is characterized in that the write/read/erase circuit writes data to the selected memory cell by injecting electrons from the semiconductor substrate into the floating gate via an oxide film, applies a voltage lower than the voltage at the semiconductor substrate to the control gate, thereby detrapping charges trapped in the oxide film or near an interface between the oxide film and the semiconductor substrate during the data writing, and performs a verification to check whether the selected memory cell is in a desired written state.

Another nonvolatile semiconductor memory device according to the present invention includes: a memory array containing a plurality of memory cells arranged in a plurality of rows and columns, each memory cell having a floating gate and a control gate formed on a semiconductor substrate; and a write/read/erase circuit that performs data writing/reading/erasing on a selected memory cell of the plurality of memory cells, and is characterized in that the write/read/erase circuit writes data to the selected memory cell by injecting electrons from the semiconductor substrate into the floating gate via an oxide film, applies an equal voltage to the control gate and the semiconductor substrate for a predetermined period of time, thereby detrapping charges trapped in the oxide film or near an interface between the oxide film and the semiconductor substrate during the data writing, and performs a verification to check whether the selected memory cell is in a desired written state.

Yet another nonvolatile semiconductor memory device according to the present invention includes: a memory array containing a plurality of memory cells arranged in a plurality of rows and columns, each memory cell having a floating gate and a control gate formed on a semiconductor substrate; and a write/read/erase circuit that performs data writing/reading/erasing on a selected memory cell of the plurality of memory cells, and is characterized in that the write/read/erase circuit erases data in the selected memory cell by drawing electrons from the floating gate into the semiconductor substrate via an oxide film, performs an over-erase verification to check whether the selected memory cell is in an over-erased state because of the data erasing, performs an over-erase recovery to write back data by injecting electrons into the floating gate from the semiconductor substrate via the oxide film if it is determined in the over-erase verification that the memory cell is in the over-erased state, applies a voltage higher than the voltage at the semiconductor substrate to the control gate, thereby detrapping charges trapped in the oxide film or near an interface between the oxide film and the semiconductor substrate during the over-erase recovery, and performs the over-erase verification again.

Still another nonvolatile semiconductor memory device according to the present invention includes: a memory array containing a plurality of memory cells arranged in a plurality of rows and columns, each memory cell having a floating gate and a control gate formed on a semiconductor substrate; and a write/read/erase circuit that performs data writing/reading/erasing on a selected memory cell of the plurality of memory cells, and is characterized in that the write/read/erase circuit erases data in the selected memory cell by drawing electrons from the floating gate into the semiconductor substrate via an oxide film, performs an over-erase verification to check whether the selected memory cell is in an over-erased state because of the data erasing, performs an over-erase recovery to write back data by injecting electrons into the floating gate from the semiconductor substrate via the oxide film if it is determined in the over-erase verification that the memory cell is in the over-erased state, applies an equal voltage to the control gate and the semiconductor substrate for a predetermined period of time, thereby detrapping charges trapped in the oxide film or near an interface between the oxide film and the semiconductor substrate during the over-erase recovery, and performs the over-erase verification again.

A nonvolatile semiconductor memory device according to the present invention performs a verification in the write sequence after charges trapped in the oxide film or near the interface between the oxide film and the semiconductor substrate are detrapped. Therefore, a change of the threshold voltage of a memory cell after completion of the write sequence can be avoided, and an adequate read margin is ensured, and the operation reliability is improved.

Another nonvolatile semiconductor memory device according to the present invention performs an over-erase verification in the erase sequence after charges trapped in the oxide film or near the interface between the oxide film and the semiconductor substrate are detrapped. Therefore, a change of the threshold voltage of a memory cell after completion of the erase sequence can be avoided, an adequate read margin is ensured, and the operation reliability is improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the entire configuration of a nonvolatile semiconductor memory device according to an embodiment 1 of the present invention;

FIG. 2 is a cross-sectional view for illustrating a program pulse applied to a memory cell in a write sequence;

FIG. 3 is a cross-sectional view for illustrating an erase pulse applied to a memory cell during data erasing in an erase sequence;

FIG. 4 is a cross-sectional view for illustrating an OER pulse applied to a memory cell during over-erase recovery in the erase sequence;

FIG. 5 is a conceptual diagram showing a threshold voltage distribution of a memory cell;

FIG. 6 is a cross-sectional view showing a state where charges in oxide film OM are detrapped after completion of the write sequence;

FIG. 7 is an energy band diagram for illustrating a state where charges in oxide film OM are detrapped after completion of the write sequence;

FIG. 8 is a cross-sectional view showing a state where charges in oxide film OM are detrapped after completion of the erase sequence;

FIG. 9 is an energy band diagram for illustrating a state where charges in oxide film OM being detrapped after completion of the erase sequence;

FIG. 10 is a flowchart showing an operation of a write sequence according to the embodiment 1;

FIG. 11 is a cross-sectional view for illustrating a PGM detrapping pulse applied to a memory cell in the write sequence shown in FIG. 10;

FIG. 12 is a time chart showing a temporal variation of gate voltage VG in the write sequence shown in FIG. 10;

FIG. 13 is a schematic diagram illustrating a state of variation of a threshold voltage of the memory cell in the write sequence shown in FIG. 10;

FIG. 14 is a flowchart showing an operation of an erase sequence according to the embodiment 1;

FIG. 15 is a cross-sectional view for illustrating an OER detrapping pulse applied to a memory cell in the erase sequence shown in FIG. 14;

FIG. 16 is a time chart showing a temporal variation of gate voltage VG after an over-erase verification in the erase sequence shown in FIG. 14;

FIG. 17 is a schematic diagram illustrating a state of variation of a threshold voltage of the memory cell after the over-erase verification in the erase sequence shown in FIG. 14;

FIG. 18 is a flowchart showing an operation of a write sequence according to a modification example of the embodiment 1 of the present invention;

FIG. 19 is a cross-sectional view for illustrating a voltage applied to a memory cell during a WAIT operation in the write sequence shown in FIG. 18;

FIG. 20 is a time chart showing a temporal variation of gate voltage VG in the write sequence shown in FIG. 18;

FIG. 21 is a flowchart showing an operation of an erase sequence according to the modification of the embodiment 1;

FIG. 22 is a time chart showing a temporal variation of gate voltage VG after an over-erase verification in the erase sequence shown in FIG. 21;

FIG. 23 is a flowchart showing an operation of a write sequence according to an embodiment 2 of the present invention;

FIG. 24 is a time chart showing a temporal variation of gate voltage VG in the write sequence shown in FIG. 23;

FIG. 25 is a schematic diagram illustrating a state of variation of a threshold voltage of a memory cell in the write sequence shown in FIG. 23;

FIG. 26 is a flowchart showing an operation of an erase sequence according to the embodiment 2 of the present invention;

FIG. 27 is a time chart showing a temporal variation of gate voltage VG after an over-erase verification in the erase sequence shown in FIG. 26;

FIG. 28 is a schematic diagram illustrating an operation of a variation of the threshold voltage of the memory cell after the over-erase verification in the erase sequence shown in FIG. 26;

FIG. 29 is a flowchart showing an operation of a write sequence according to a modification example of the embodiment 2 of the present invention; and

FIG. 30 is a flowchart showing an operation of an erase sequence according to the modification example of the embodiment 2 of the present invention.

### DESCRIPTION OF THE PREFERRED EMBODIMENTS

### Embodiment 1

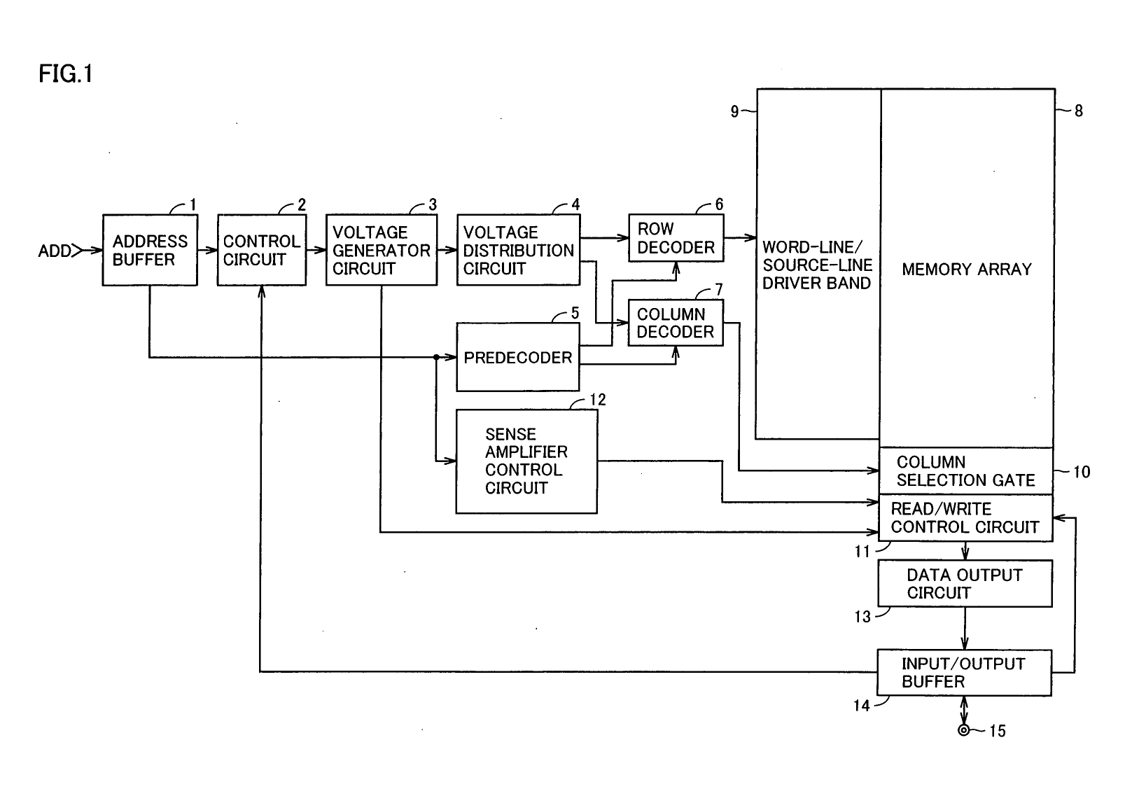

FIG. 1 is a block diagram showing the entire configuration of a nonvolatile semiconductor memory device according to an embodiment 1 of the present invention. In FIG. 1, the nonvolatile semiconductor memory device includes an address buffer 1 that receives an external address signal ADD and outputs an internal address signal, a control circuit 2 that receives the internal address signal from address buffer 1 and executes various kinds of operation controls, a voltage generator circuit 3 that generates a voltage used for each type of operation sequence based on the instruction from control circuit 2, and a voltage distribution circuit 4 that receives the voltage generated by voltage generator circuit 3 and adjusts the voltage level for distribution.

In addition, the nonvolatile semiconductor memory device has a predecoder 5 that receives the internal address signal from address buffer 1 and generates a predecoded row signal and a predecoded column signal, a row decoder 6 that generates a row selection signal based on the predecoded row signal output from predecoder 5, a column decoder 7 that generates a column selection signal based on the predecoded column signal output from predecoder 5, a memory array 8 containing memory cells integrated and arranged in a plurality of rows and columns, a word-line/source-line driver band 9 that drives a word line and a source line each associated with a memory cell row according to the row selection signal from row decoder 6, a column selection gate 10 that selects a bit line associated with a memory cell column according to the column selection signal from column decoder 7, a read/write control circuit 11 that individually amplifies read data during data reading and data to be written during data writing with a sense amplifier and outputs the amplified data, a data output circuit 13 that outputs data during data reading, an input/output buffer 14 that outputs the read data received from data output circuit 13 to an external terminal 15 after buffering and transfers the data to be written received from external terminal 15 to a write driver in read/write control circuit 11, and a sense amplifier control circuit 12 that controls the sense amplifier in read/write control circuit 11.

Control circuit 2 includes a command control circuit that generates commands for indicating various operation sequences (read sequence, write sequence, erase sequence and the like) based on the internal address signal from address buffer 1, a voltage control circuit that controls the operation voltage of each circuit generated by voltage generator circuit 3, a verification control circuit that controls a verification operation in the write sequence and erase sequence, and the like.

In the write sequence and erase sequence, at the stage of applying a program pulse (write pulse) and an erase pulse, under the control by the voltage control circuit in control circuit 2, voltage generator circuit 3 controls a gate voltage VG, a source voltage VS and a substrate voltage VWELL of a selected memory cell in memory array 8 via voltage distribution circuit 4 and row decoder 6, and controls a drain voltage VD of the selected memory cell in memory array 8 via voltage distribution circuit 4 and column decoder 7. Furthermore, in the write sequence and erase sequence, at the stage of performing the verification operation, the verification operation is achieved by controlling under the control by the voltage control circuit in control circuit 2 voltage generator circuit 3 to apply a read voltage to the selected memory cell in memory array 8 and read/write control circuit 11 reading data and feeding the read data back to control circuit 2 via input/output buffer 14.

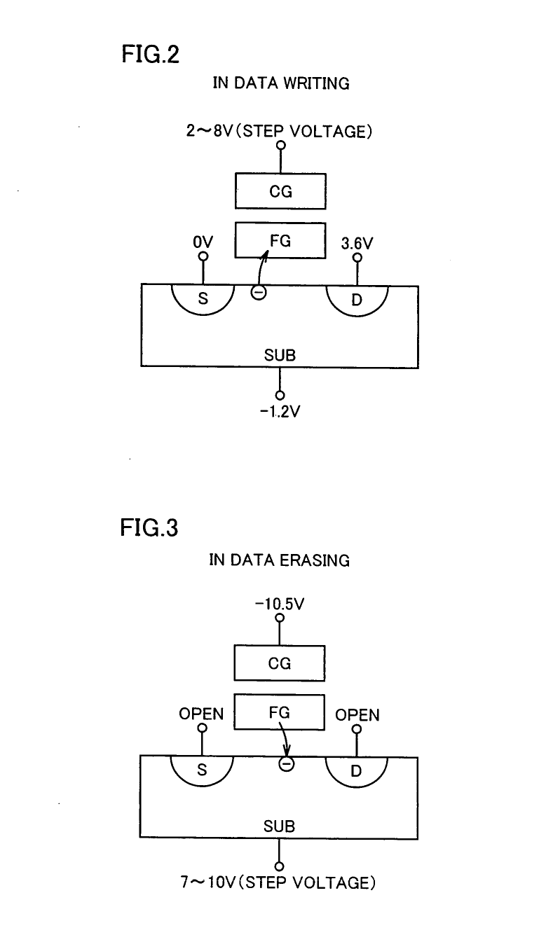

FIG. 2 is a cross-sectional view for illustrating a program pulse applied to a memory cell in the write sequence. With reference to FIG. 2, the memory cell includes a source S and a drain D that are impurity regions formed at a surface of a semiconductor substrate (silicon substrate) SUB, a floating gate FG formed on a region between the source S and the drain D, and also a control gate CG formed on the floating gate FG. In addition, an oxide film OM is formed between the floating gate FG and the semiconductor substrate SUB (not shown).

Gate voltage VG that increases stepwise from 2 V to 8 V is applied to control gate CG via a word line. Source voltage VS of 0 V is applied to source S via a source line. Drain voltage VD of 3.6 V is applied to drain D via a bit line. Substrate voltage VWELL of −1.2 V is applied to semiconductor substrate SUB. Thus, electrons are injected into floating gate FG via oxide film OM by the channel hot electron injection phenomenon, and data writing is achieved. The threshold voltage of the memory cell varies with the amount of charges injected into floating gate FG, and thus, the memory cell can store data according to the level (high or low) of the threshold voltage.

FIG. 3 is a cross-sectional view for illustrating an erase pulse applied to a memory cell during data erasing in the erase sequence. With reference to FIG. 3, gate voltage VG of −10.5 V is applied to control gate CG via a word line. Source S and drain D are opened. Substrate voltage VWELL that increases stepwise from 7 V to 10 V is applied to semiconductor substrate SUB. Thus, electrons are drawn from floating gate via oxide film OM by the Fowler-Nordheim tunneling phenomenon, and data erasing is achieved.

After the data erasing, the memory cell may be in an over-erased state, in which the threshold voltage thereof exceeds a predetermined range (or state in which an excessive amount of electrons are drawn from the floating gate). Thus, an over-erase recovery is performed to write data back to the memory cell in the over-erased state.

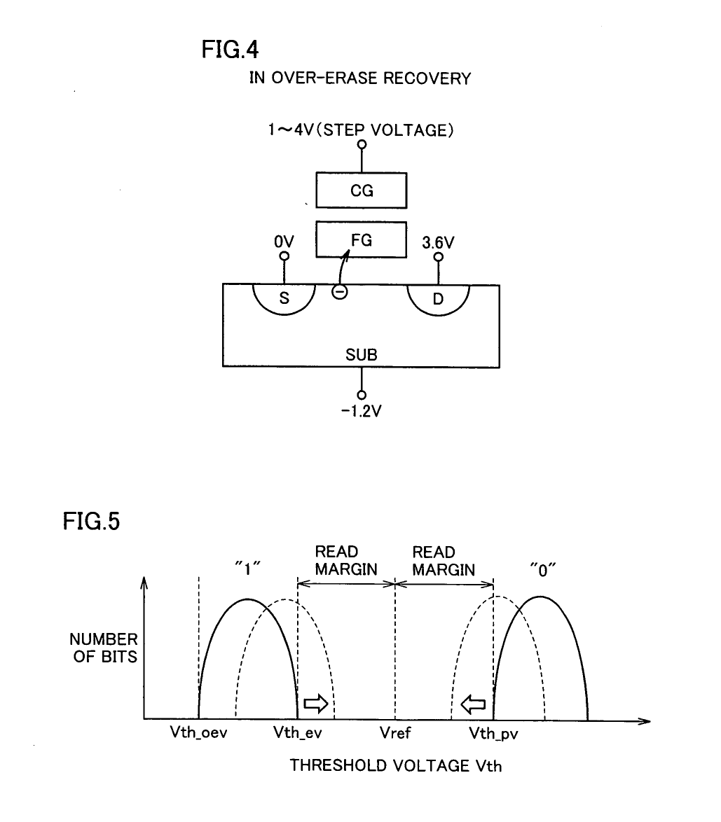

FIG. 4 is a cross-sectional view for illustrating an over-erase recovery (OER) pulse applied to a memory cell during over-erase recovery in the erase sequence. With reference to FIG. 4, gate voltage VG that increases stepwise from 1 V to 4 V is applied to control gate CG via a word line. Source voltage VS of 0 V is applied to source S via a source line. Drain voltage VD of 3.6 V is applied to drain D via a bit line. Substrate voltage VWELL of −1.2 V is applied to semiconductor substrate SUB. Thus, electrons are injected into floating gate FG via oxide film OM by the channel hot electron injection phenomenon, and data is written back.

FIG. 5 is a conceptual diagram showing a threshold voltage distribution of a memory cell. With reference to FIG. 5, the programmed state (written state) after execution of data writing corresponds to data “0”, and the erased state after data erasing corresponds to data “1”. A data read reference value Vref is set to lie between the threshold voltage distribution of the programmed state and the threshold voltage distribution of the erased state.

During data writing, using the channel hot electron injection phenomenon, a program pulse is applied so that the threshold voltage of the memory cell changes from a low level to a high level. Specifically, a program pulse is applied until the lower limit value of the threshold voltage distribution of the memory cell reaches a program verification reference value Vth_pv while performing program verification to determine whether the lower limit value of the threshold voltage distribution has increased to program verification reference value Vth_pv or not.

During data erasing, using the Fowler-Nordheim tunneling phenomenon, an erase pulse is applied so that the threshold voltage of the memory cell changes from a high level to a low level. Specifically, an erase pulse is applied until the upper limit value of the threshold voltage distribution of the memory cell reaches an erase verification reference value Vth_ev while performing erase verification to determine whether the upper limit value of the threshold voltage distribution has decreased to erase verification reference value Vth_ev or not. Furthermore, in the over-erase recovery, an OER pulse is applied until the lower limit value of the threshold voltage distribution of the memory cell reaches an OER verification reference value Vth_oev while performing over-erase verification to determine whether the lower limit value of the threshold voltage distribution becomes lower than OEM verification reference value Vth_oev or not.

During data reading, memory data are differentiated according to data read reference value Vref Specifically, if the threshold voltage is lower than data read reference value Vref, the data is determined to be in the erased state (“1”), and if the threshold voltage is higher than data read reference value Vref, the data is determined to be in the programmed state (“0”).

If the data rewrite operation that involves electron injection and drawing into and from floating gate FG via oxide film OM is repeated, oxide film OM gradually deteriorates. As a result, a trap site that traps charges (holes and electrons) is formed in oxide film OM, and charges are accumulated in oxide film OM or near the interface between oxide film OM and the semiconductor substrate (referred to as oxide film interface, hereinafter) during data writing or during over-erase recovery in the erase sequence.

According to prior art, the verification operation is performed under the condition that charges are trapped in oxide film OM or near the oxide film interface, and therefore, there is a problem that, after completion of the write sequence or erase sequence, the trapped charges are detrapped (released) in a short time (on the order of μs to ms).

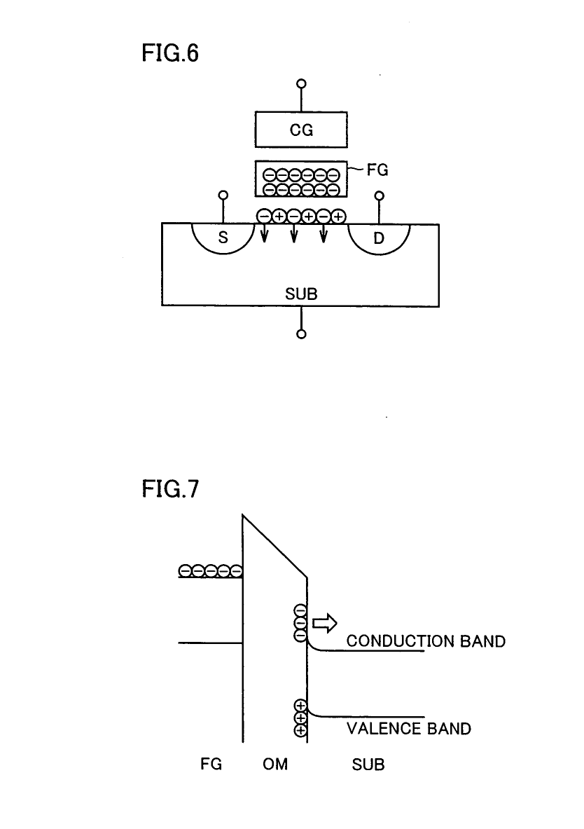

FIG. 6 is a cross-sectional view showing a state where charges in oxide film OM are detrapped after completion of the write sequence. FIG. 7 is an energy band diagram for illustrating a state where charges in oxide film OM are detrapped after completion of the write sequence. With reference to FIG. 6, when electrons are injected into floating gate FG via oxide film OM during data writing, electrons and holes are trapped in oxide film OM or near the oxide film interface. Then, after completion of the write sequence, the trapped electrons are detrapped. With reference to FIG. 7, during data writing, electrons are accumulated in the conduction band of floating gate FG, and electrons and holes are trapped in oxide film OM or near the oxide film interface. Then, after completion of the write sequence, the trapped electrons are detrapped into the conduction band of semiconductor substrate SUB.

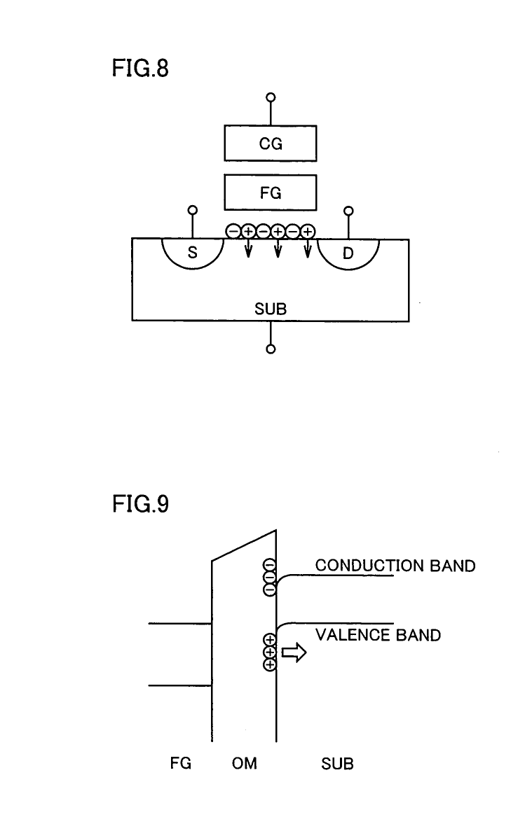

FIG. 8 is a cross-sectional view showing a state where charges in oxide film OM are detrapped after completion of the erase sequence. FIG. 9 is an energy band diagram for illustrating a state where charges in oxide film OM are detrapped after completion of the erase sequence. With reference to FIG. 8, when electrons are injected into floating gate FG via oxide film OM during over-erase recovery in the erase sequence, electrons and holes are trapped in oxide film OM or near the oxide film interface. After completion of the erase sequence, the trapped holes are detrapped. With reference to FIG. 9, during over-erase recovery in the erase sequence, electrons and holes are trapped in oxide film OM or near the oxide film interface. After completion of the erase sequence, the trapped holes are detrapped into the valence band of semiconductor substrate SUB.

Referring back to FIG. 5, as shown by dotted lines, when electrons in oxide film OM are detrapped after completion of the write sequence, the threshold voltage of the memory cell decreases to approach data read reference value Vref Besides, when holes in oxide film OM is detrapped after completion of the erase sequence, the threshold voltage of the memory cell increases to approach data read reference value Vref.

As described above, the conventional nonvolatile semiconductor memory device performs the verification operation under the condition that charges are trapped in oxide film OM or near the oxide film interface, and the charges in oxide film OM are detrapped after completion of the write sequence or erase sequence, so that the threshold voltage of the memory cell changes. As a result, there is a problem that the read margin is reduced, and therefore, the operation reliability is reduced. Furthermore, for example, in the case of using a multivalued technique that allows plural pieces of data to be written in each memory cell, such as a four-valued memory that allows 2-bit data (“11”, “10”, “01”, “00”) to be written in one memory cell, intervals between the threshold voltage distributions associated with the respective pieces of data are narrow, so that the effect of the change of the threshold voltage of the memory cell becomes greater.

Thus, according to this embodiment 1, immediately before the program verification operation in the write sequence, and immediately before the over-erase verification operation in the erase sequence, charges trapped in oxide film OM or near the oxide film interface are forcedly detrapped.

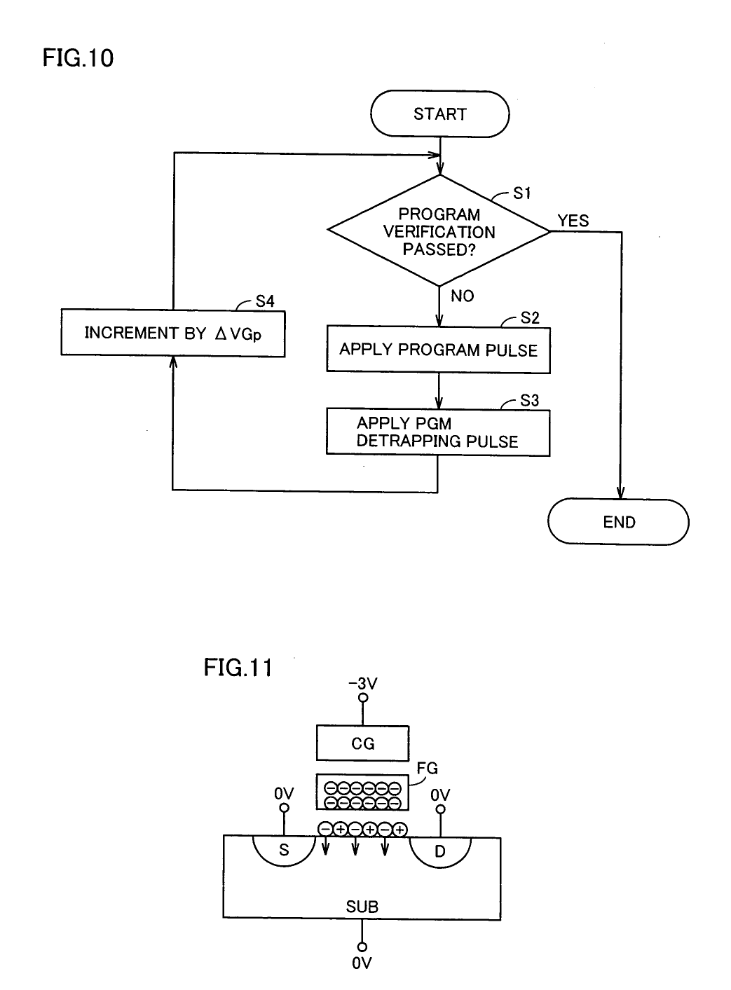

FIG. 10 is a flowchart showing an operation of a write sequence according to the embodiment 1. With reference to FIG. 10, in step S1, program verification is performed. In the program verification, if it is determined that the lower limit value of the threshold voltage distribution of the memory cell is lower than program verification reference value Vth_pv (Fail), the process proceeds to step S2.

In step S2, a program pulse is applied to the memory cell, electrons are injected into floating gate FG via oxide film OM by the channel hot electron injection phenomenon to achieve data writing. In this regard, the initial value of gate voltage VG (step voltage) at the time of application of the program pulse is Vpp_pv. Then, in step S3, a PGM detrapping pulse is applied to the memory cell, and the electrons trapped in oxide film OM or near the oxide film interface are forcedly detrapped.

FIG. 11 is a cross-sectional view for illustrating a PGM detrapping pulse applied to a memory cell in the write sequence shown in FIG. 10. With reference to FIG. 11, gate voltage VG of a predetermined value Vpp_pdv (−3 V) is applied to control gate CG via a word line. Predetermined value Vpp_pdv (−3 V) is set at a level enough to prevent the electrons injected into floating gate FG from being drawn therefrom. Specifically, predetermined value Vpp_pdv is set at a negative voltage value smaller in absolute value than gate voltage VG (−10.5 V) applied during data erasing. Source voltage VS of 0 V is applied to source S via a source line. Drain voltage VD of 0 V is applied to drain D via a bit line. Substrate voltage VWELL of 0 V is applied to semiconductor substrate SUB. Thus, the electrons trapped in oxide film OM or near the oxide film interface during data writing are detrapped.

Referring back to FIG. 10, then, in step S4, gate voltage VG at the time of application of the program pulse is incremented by ΔVGp, and the process returns to step S1. Steps S1 to S4 are repeated until the lower limit value of the threshold voltage distribution of the memory cell reaches program verification reference value Vth_pv. Then, when it is determined in the program verification in step S1 that the lower limit value of the threshold voltage distribution of the memory cell has increased to program verification reference value Vth_pv (Pass), it is determined that data writing is completed, and the write sequence is ended.

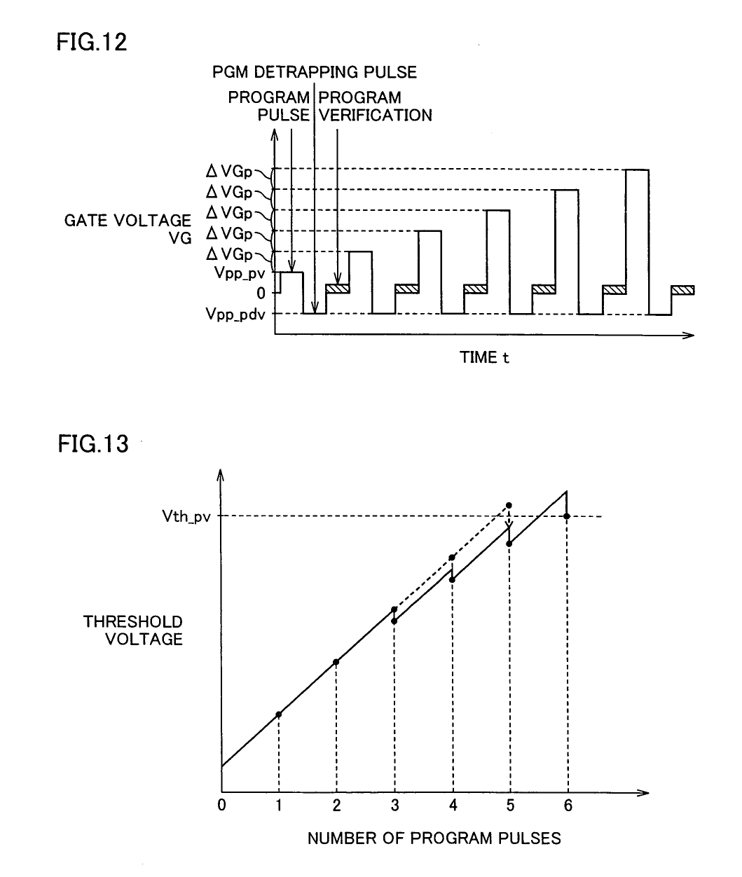

FIG. 12 is a time chart showing a temporal variation of gate voltage VG in the write sequence shown in FIG. 10. With reference to FIG. 12, the program pulse is applied to the memory cell, and gate voltage VG of initial value Vpp_pv is applied to control gate CG. Then, the PGM detrapping pulse is applied to the memory cell, and gate voltage VG of predetermined value Vpp_pdv is applied to control gate CG. Then, the program verification is performed. In the program verification, if the lower limit value of the threshold voltage distribution of the memory cell does not increase to program verification reference value Vth_pv, gate voltage VG at the time of application of the program pulse is incremented by ΔVGp, and the program pulse is applied to the memory cell again. Then, the procedure described above is repeated until the lower limit value of the threshold voltage distribution of the memory cell reaches program verification reference value Vth_pv.

FIG. 13 is a schematic diagram illustrating a state of variation of the threshold voltage of the memory cell in the write sequence shown in FIG. 10. With reference to FIG. 13, when the program pulse is applied to the memory cell, and electrons are injected into floating gate FG via oxide film OM by the channel hot electron injection phenomenon, the threshold voltage of the memory cell increases as shown by the solid line.

In the write sequence, as described above, application of the program pulse, application of the PGM detrapping pulse, and the program verification operation are repeated. In this example, if injection of electrons into floating gate FG via oxide film OM is repeated three times, charges become trapped in oxide film OM or near the oxide film interface because of deterioration of oxide film OM. Thus, in response to the application of the PGM detrapping pulse following the third application of the program pulse to the memory cell, the trapped electrons are detrapped, and the threshold voltage of the memory cell decreases. Then, the same operation is repeated, and in response to the application of the PGM detrapping pulse following the sixth application of the program pulse to the memory cell, the threshold voltage of the memory cell decreases. In the following program verification, it is determined that the lower limit value of the threshold voltage distribution of the memory cell has increased to program verification reference value Vth_pv.

According to prior art, the PGM detrapping pulse is not applied. Therefore, as shown by the dotted line, in the program verification following the fifth application of the program pulse to the memory cell, it is determined that the lower limit value of the threshold voltage distribution of the memory cell has increased to program verification reference value Vth_pv, and then, the trapped electrons are detrapped, and the threshold voltage of the memory cell decreases. That is, the threshold voltage of the memory cell changes after completion of the write sequence, and thus, there is a problem that the read margin is reduced, and the operation reliability is reduced.

However, according to this embodiment 1, the program verification is performed after the PGM detrapping pulse is applied to the memory cell. In other words, the program verification is performed after the electrons trapped in oxide film OM or near the oxide film interface are detrapped. Therefore, a change of the threshold voltage of the memory cell after completion of the write sequence can be avoided, an adequate read margin is ensured, and the operation reliability is improved.

In addition, value Vpp_pdv of gate voltage VG at the time of application of the PGM detrapping pulse is set at a negative voltage value (−3 V, for example) smaller in absolute value than the voltage difference between gate voltage VG applied at the time of data erasing (−10.5 V) and substrate voltage VWELL (7-10 V). Thus, since the voltage level is low, an increase of operation time can be reduced.

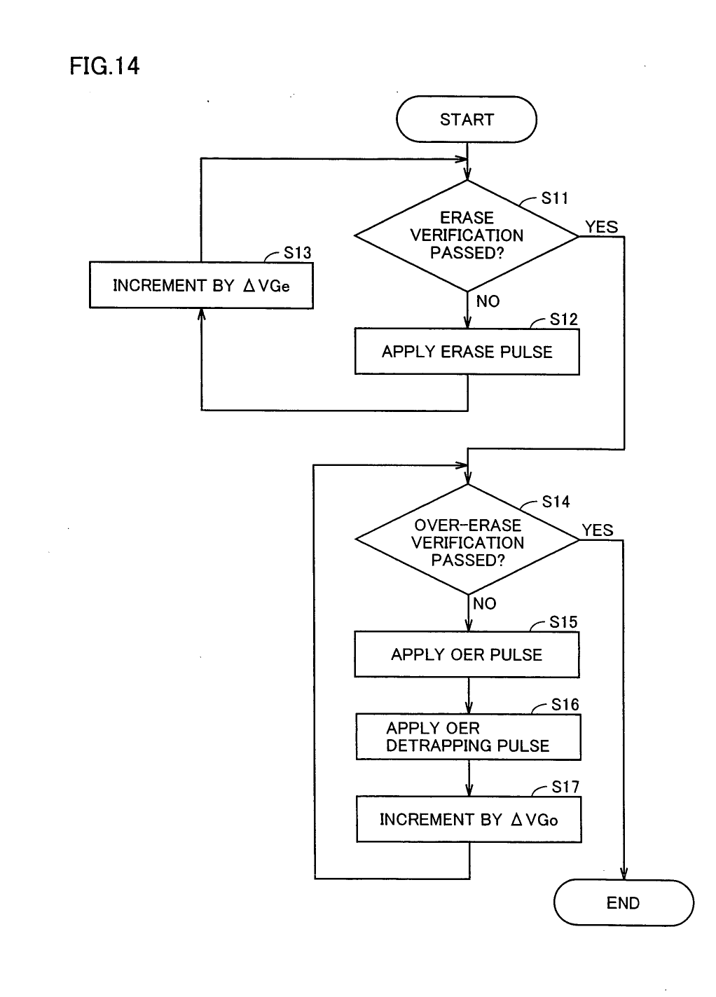

FIG. 14 is a flowchart showing an operation of an erase sequence according to the embodiment 1. With reference to FIG. 14, in step S11, erase verification is performed. In the erase verification, if the upper limit value of the threshold voltage distribution of the memory cell is higher than erase verification reference value Vth_ev (Fail), the process proceeds to step S12, where an erase pulse is applied to the memory cell, and electrons are drawn from floating gate via oxide film OM by the Fowler-Nordheim tunneling phenomenon to achieve data erasing. The initial value of substrate voltage VWELL (step voltage) at the time of application of the erase pulse is Vpp_ev.

Then, in step S13, substrate voltage VWELL at the time of application of the erase pulse is incremented by ΔVGe, and the process returns to step S11. Steps S11 to S13 are repeated until the upper limit value of the threshold voltage distribution of the memory cell reaches erase verification reference value Vth_ev. Then, if it is determined in the erase verification in step S11 that the upper limit value of the threshold voltage distribution of the memory cell has decreased to erase verification reference value Vth_ev, it is determined that data erasing is completed (Pass), and the process proceeds to step S14.

In step S14, over-erase verification is performed to check whether the memory cell is in the over-erased state or not. In this step, if it is determined that the lower limit value of the threshold voltage distribution of the memory cell is lower than OER verification reference value Vth_oev, the process proceeds to step S15, where over-erase recovery is performed to write data back to the memory cell in the over-erased state. In step S15, an OER pulse is applied to the memory cell, and electrons are injected to floating gate FG via oxide film OM by the channel hot electron injection phenomenon to achieve data write-back. The initial value of gate voltage VG (step voltage) at the time of application of the OER pulse is Vpp_oev. Then, the process proceeds to step S16, where an OER detrapping pulse is applied to the memory cell, and the holes trapped in oxide film OM or near the oxide film interface are forcedly detrapped.

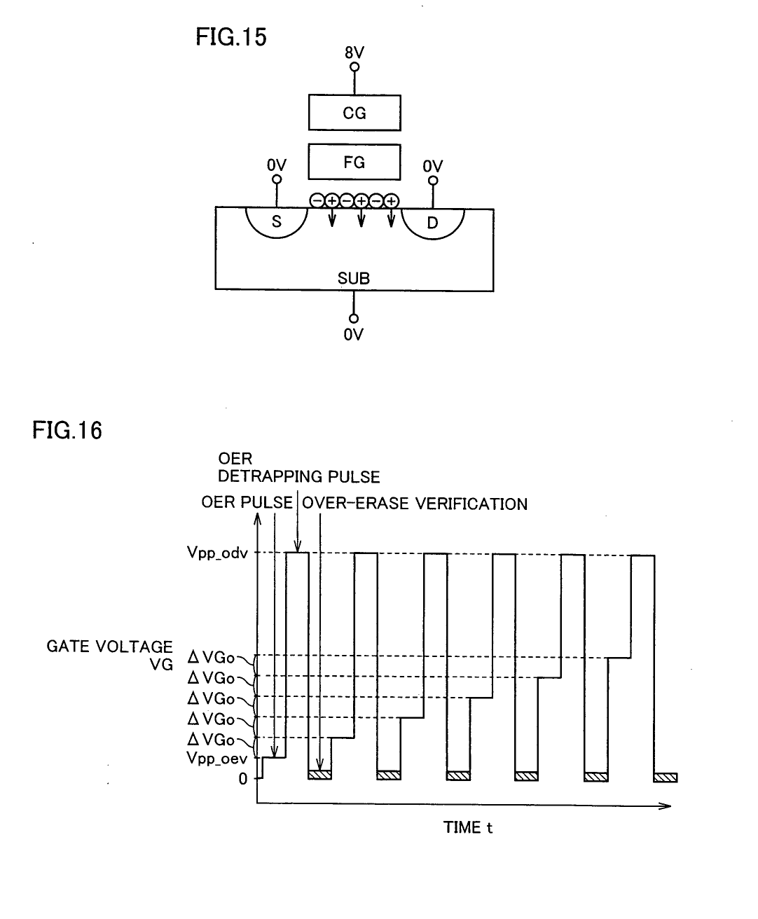

FIG. 15 is a cross-sectional view for illustrating an OER detrapping pulse applied to the memory cell in the erase sequence shown in FIG. 14. With reference to FIG. 15, gate voltage VG of a predetermined value Vpp_odv (8 V) is applied to control gate CG via a word line. Predetermined value Vpp_odv (8 V) is set at a level enough to prevent electrons from being injected into floating gate FG. Source voltage VS of 0 V is applied to source S via a source line. Drain voltage VD of 0 V is applied to drain D via a bit line. Substrate voltage VWELL of 0 V is applied to semiconductor substrate SUB. Thus, holes trapped in oxide film OM or near the oxide film interface are detrapped.

Referring back to FIG. 14, the process then proceeds to step S17, where gate voltage VG at the time of application of the OER pulse is incremented by ΔVGo, and then, the process returns to step S14. Steps S14 to S17 are repeated until the lower limit value of the threshold voltage distribution of the memory cell reaches OER verification reference value Vth_oev. Then, if it is determined in the over-erase verification in step S14 that the lower limit value of the threshold voltage distribution of the memory cell has increased to OER verification reference value Vth_oev, it is determined that the memory cell is not in the over-erased state, and the erase sequence is ended.

FIG. 16 is a time chart showing a temporal variation of gate voltage VG after the over-erase verification in the erase sequence shown in FIG. 14. The OER pulse is applied to the memory cell, and gate voltage VG of initial value Vpp_oev is applied to control gate CG. Then, the OER detrapping pulse is applied to the memory cell, and gate voltage VG of predetermined value Vpp_odv is applied to control gate CG. Then, the over-erase verification is performed. In the over-erase verification, if it is determined that the lower limit value of the threshold voltage distribution of the memory cell is lower than OER verification reference value Vth_oev, the OER pulse is applied to the memory cell in the over-erased state, and gate voltage VG of initial value Vpp_oev is applied to control gate CG.

Then, the OER detrapping pulse is applied to the memory cell, and gate voltage VG of predetermined value Vpp_odv is applied to control gate CG. Then, gate voltage VG at the time of application of the OER pulse is incremented by ΔVGo, and then, the over-erase verification is performed again. Then, the procedure described above is repeated until the lower limit value of the threshold voltage distribution of the memory cell reaches OER verification reference value Vth_oev.

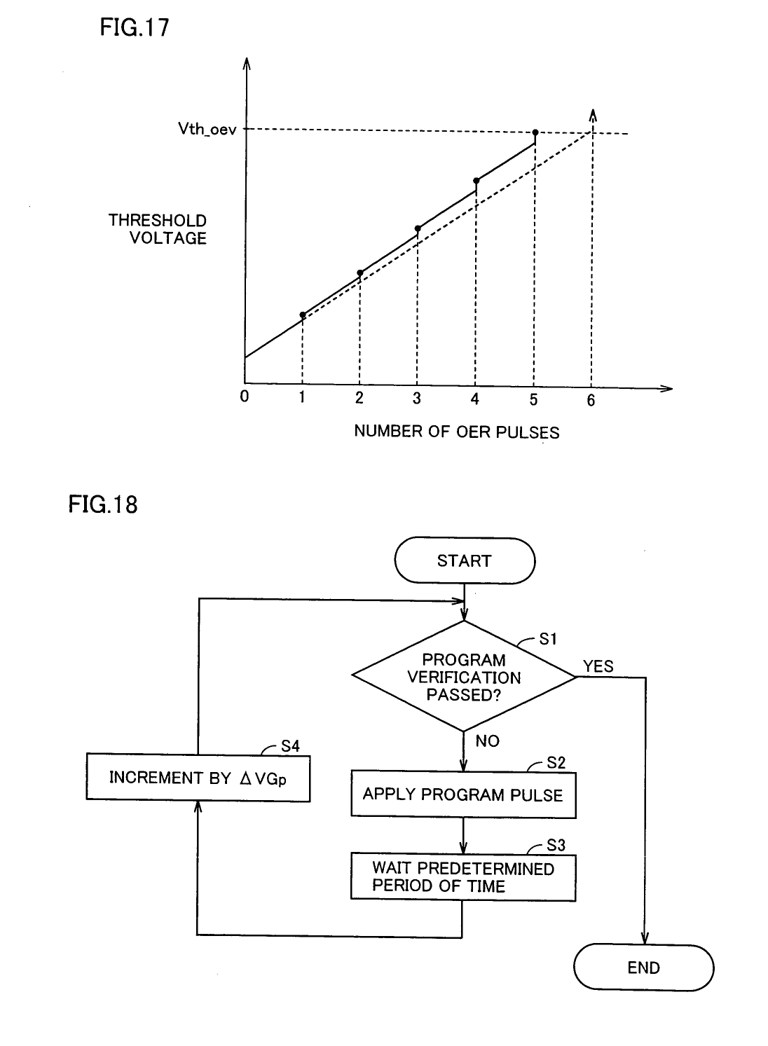

FIG. 17 is a schematic diagram illustrating a state of variation of the threshold voltage of the memory cell after the over-erase verification in the erase sequence shown in FIG. 14. With reference to FIG. 17, when the OER pulse is applied to the memory cell, and electrons are injected into floating gate FG via oxide film OM by the channel hot electron injection phenomenon, the threshold voltage of the memory cell increases as shown by the solid line.

In the erase sequence, as described above, application of the OER pulse, application of the OER detrapping pulse, and the over-erase verification operation are repeated. In this shown example, in response to the application of the OER detrapping pulse following the first application of the OER pulse to the memory cell, holes trapped in oxide film OM or near the oxide film interface are detrapped because of deterioration of oxide film OM, and the threshold voltage of the memory cell increases. Then, the same operation is repeated, and in response to the application of the OER detrapping pulse following the fifth application of the OER pulse to the memory cell, the threshold voltage of the memory cell increases. In the following over-erase verification, it is determined that the lower limit value of the threshold voltage distribution of the memory cell has increased to over-erase verification reference value Vth_oev.

According to prior art, the OER detrapping pulse is not applied. Therefore, as shown by the dotted line, in the over-erase verification following the sixth application of the OER pulse to the memory cell, it is determined that the lower limit value of the threshold voltage distribution of the memory cell has increased to over-erase verification reference value Vth_oev, and then, the holes trapped in oxide film OM or near the oxide film interface are detrapped, and the threshold voltage of the memory cell decreases. That is, the threshold voltage of the memory cell changes after completion of the erase sequence, and thus, there is a problem that the read margin is reduced, and the operation reliability is reduced.

However, according to this embodiment 1, the over-erase verification is performed after the OER detrapping pulse is applied to the memory cell. In other words, the over-erase verification is performed after the holes trapped in oxide film OM or near the oxide film interface are detrapped. Therefore, a change of the threshold voltage of the memory cell after completion of the erase sequence can be avoided, an adequate read margin is ensured, and the operation reliability is improved.

Specific voltage values of the gate voltage, the source voltage, the drain voltage and the substrate voltage shown in this embodiment 1 are only for illustrative purposes, and the present invention is not limited thereto.

### Modification Example of Embodiment 1

FIG. 18 is a flowchart showing an operation of a write sequence according to a modification example of the embodiment 1 of the present invention, which is to be compared with FIG. 10. FIG. 18 differs from FIG. 10 in that, in step S3, the sequence has a WAIT operation of a predetermined period of time, instead of applying the PGM detrapping pulse to the memory cell.

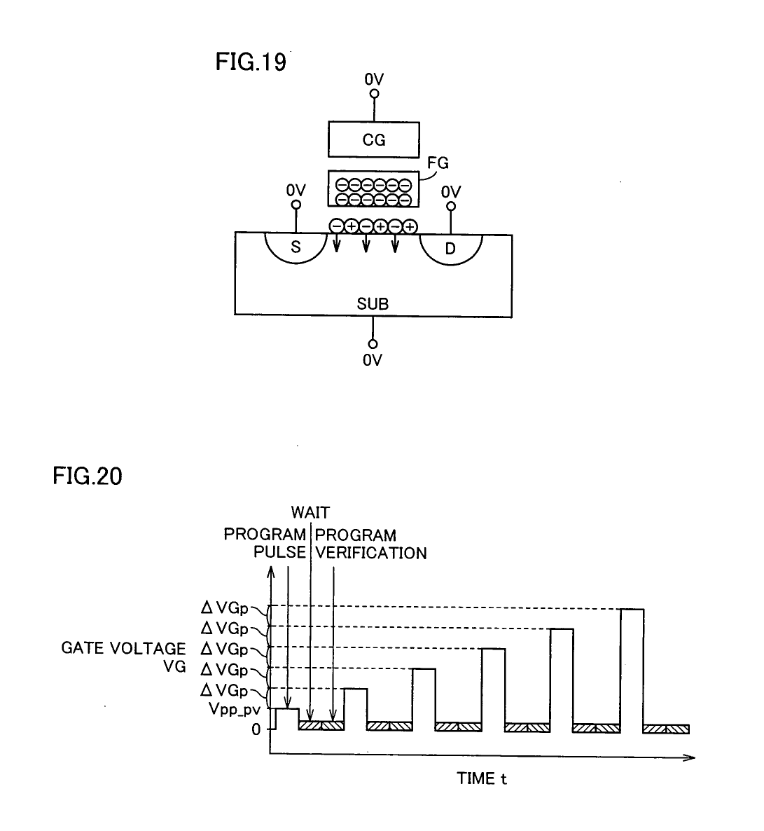

FIG. 19 is a cross-sectional view for illustrating a voltage applied to the memory cell during the WAIT operation in the write sequence shown in FIG. 18, which is to be compared with FIG. 11. FIG. 19 differs from FIG. 11 in that gate voltage VG applied to control gate CG is set at 0 V. After the WAIT state is kept for a predetermined period of time (on the order of μs to ms) with gate voltage VG, source voltage VS, drain voltage VD and substrate voltage VWELL all set at 0 V in this way, electrons trapped in oxide film OM or near the oxide film interface are automatically detrapped.

FIG. 20 is a time chart showing a temporal variation of gate voltage VG in the write sequence shown in FIG. 18, which is to be compared with FIG. 12. FIG. 20 differs from FIG. 12 in that the write sequence has a WAIT operation of a predetermined period of time instead of applying the PGM detrapping pulse to the memory cell. In this case also, the threshold voltage of the memory cell changes as shown in FIG. 13. Therefore, a change of the threshold voltage of the memory cell after completion of the write sequence can be avoided, an adequate read margin is ensured, and the operation reliability is improved.

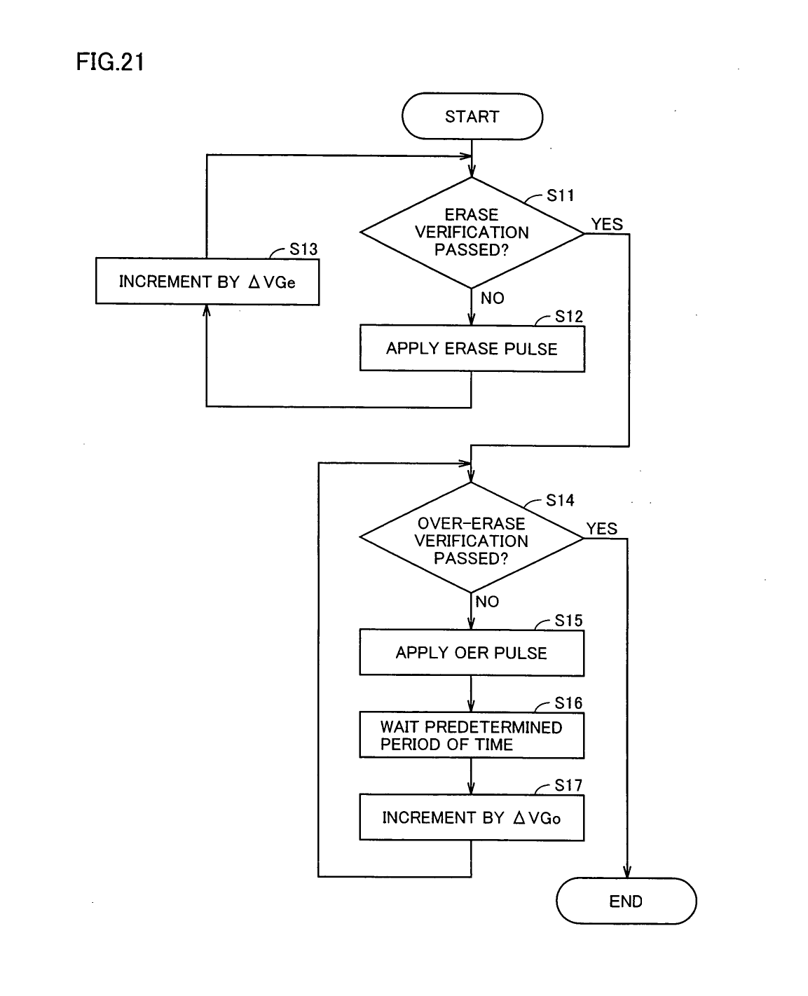

FIG. 21 is a flowchart showing an operation of an erase sequence according to the modification example of the embodiment 1, which is to be compared with FIG. 14. FIG. 21 differs from FIG. 14 in that, in step S16, the erase sequence has a WAIT operation of a predetermined period of time instead of applying the OER detrapping pulse to the memory cell.

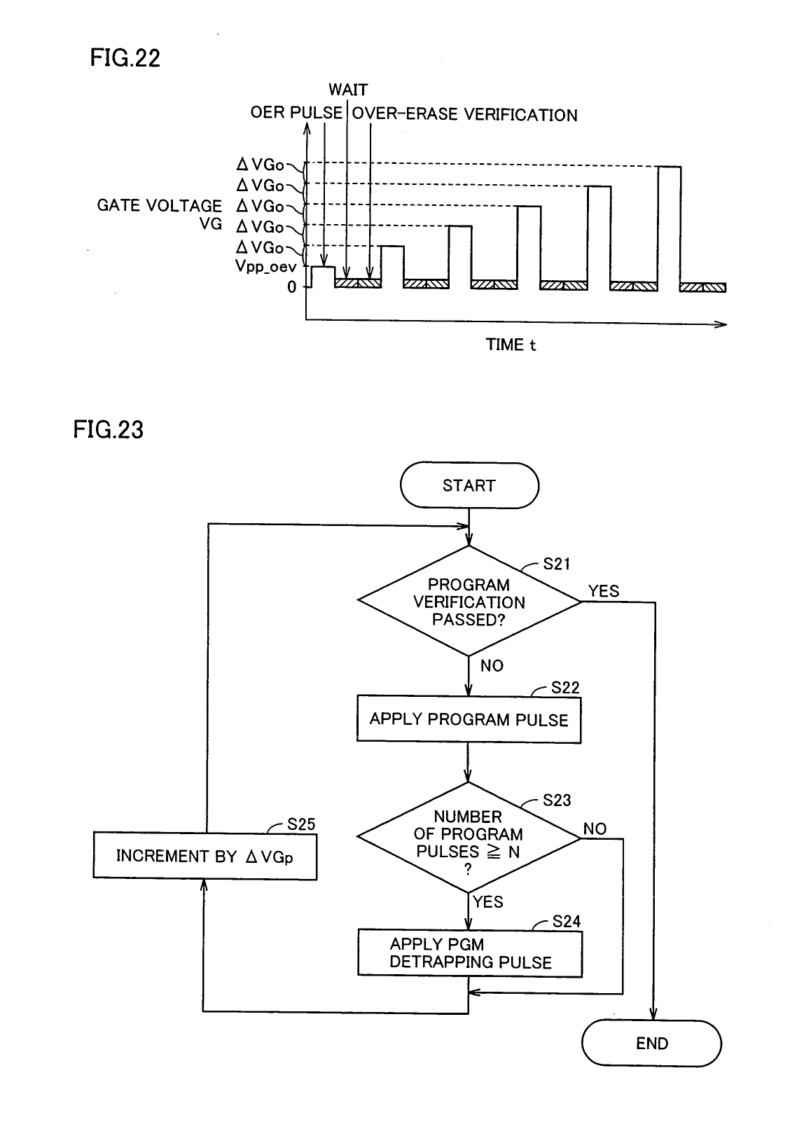

FIG. 22 is a time chart showing a temporal variation of gate voltage VG after the over-erase verification in the erase sequence shown in FIG. 21, which is to be compared with FIG. 16. FIG. 22 differs from FIG. 16 in that the erase sequence has a WAIT operation of a predetermined period of time instead of applying the OER detrapping pulse to the memory cell. In this case also, the threshold voltage of the memory cell changes as shown in FIG. 17. Therefore, a change of the threshold voltage of the memory cell after completion of the erase sequence can be avoided, an adequate read margin is ensured, and the operation reliability is improved.

### Embodiment 2

FIG. 23 is a flowchart showing a write sequence according to an embodiment 2 of the present invention, which is to be compared with FIG. 10. Steps S21, S22, S24 and S25 in FIG. 23 correspond to steps S1 to S4 in FIG. 10, respectively. In step S23, it is determined whether the number of program pulses applied to the memory cell has reached a predetermined number N. If the number of program pulses is less than N, the process proceeds to step S25 by skipping step S24, or if the number of program pulses is equal to or more than N, the process proceeds to step S24.

For example, if the number N is set at a half of the total number of program pulses, no PGM detrapping pulse is applied to the memory cell in the first half of the write sequence, and the PGM detrapping pulse is applied to the memory cell only in the latter half of the write sequence.

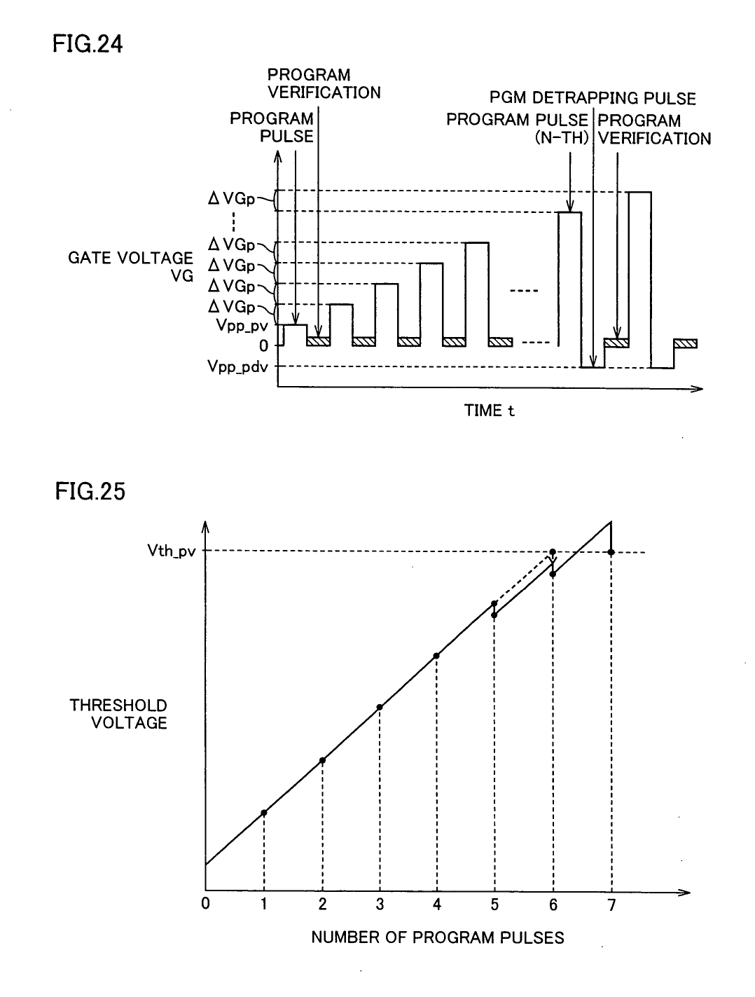

FIG. 24 is a time chart showing a temporal variation of gate voltage VG in the write sequence shown in FIG. 23, which is to be compared with FIG. 12. FIG. 20 differs from FIG. 12 in that no PGM detrapping pulse is applied until the number of program pulses reaches N.

Thus, since application of the PGM detrapping pulse to the memory cell can be prevented in the first half of the write sequence, in which deterioration of oxide film OM is considered to be relatively small, the operation time can be reduced.

FIG. 25 is a schematic diagram illustrating a state of variation of the threshold voltage of the memory cell in the write sequence shown in FIG. 23, which is to be compared with FIG. 13. In this example, when the number of program pulses is 5 or more, the PGM detrapping pulse is applied. Then, in response to the application of the PGM detrapping pulse following the seventh application of the program pulse to the memory cell, the threshold voltage of the memory cell decreases. In the following program verification, it is determined that the lower limit value of the threshold voltage distribution of the memory cell has increased to program verification reference value Vth_pv.

According to prior art, the PGM detrapping pulse is not applied. Therefore, as shown by the dotted line, in the program verification following the sixth application of the program pulse to the memory cell, it is determined that the lower limit value of the threshold voltage distribution of the memory cell has increased to program verification reference value Vth_pv, and then, the electrons trapped in oxide film OM or near the oxide film interface are detrapped, and the threshold voltage of the memory cell decreases.

However, according to this embodiment 2, the program verification is performed after the PGM detrapping pulse is applied to the memory cell. In other words, the program verification is performed after the electrons trapped in oxide film OM or near the oxide film interface are detrapped. Therefore, a change of the threshold voltage of the memory cell after completion of the write sequence can be avoided, an adequate read margin is ensured, and the operation reliability is improved.

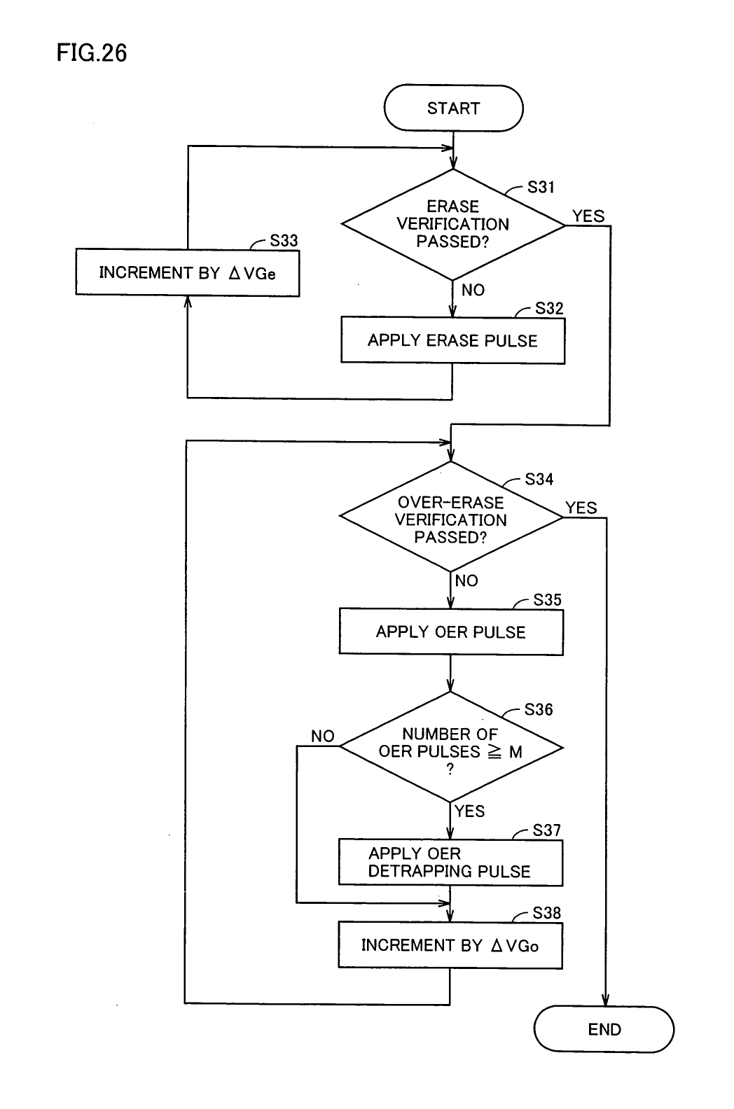

FIG. 26 is a flowchart showing an operation of an erase sequence according to the embodiment 2 of the present invention, which is to be compared with FIG. 14. Steps S31 to S35, S37 and S38 in FIG. 26 correspond to steps S11 to S17 in FIG. 14, respectively. In step S36, it is determined whether or not the number of OER pulses applied to the memory cell has reached a predetermined number M. If the number of OER pulses is less than M, the process proceeds to step S38 by skipping step S37, or if the number of OER pulses is equal to or more than M, the process proceeds to step S37.

For example, if the number M is set at a half of the total number of OER pulses, no OER detrapping pulse is applied to the memory cell in the first half of the over-erase recovery operation in the erase sequence, and the OER detrapping pulse is applied to the memory cell only in the latter half of the over-erase recovery operation.

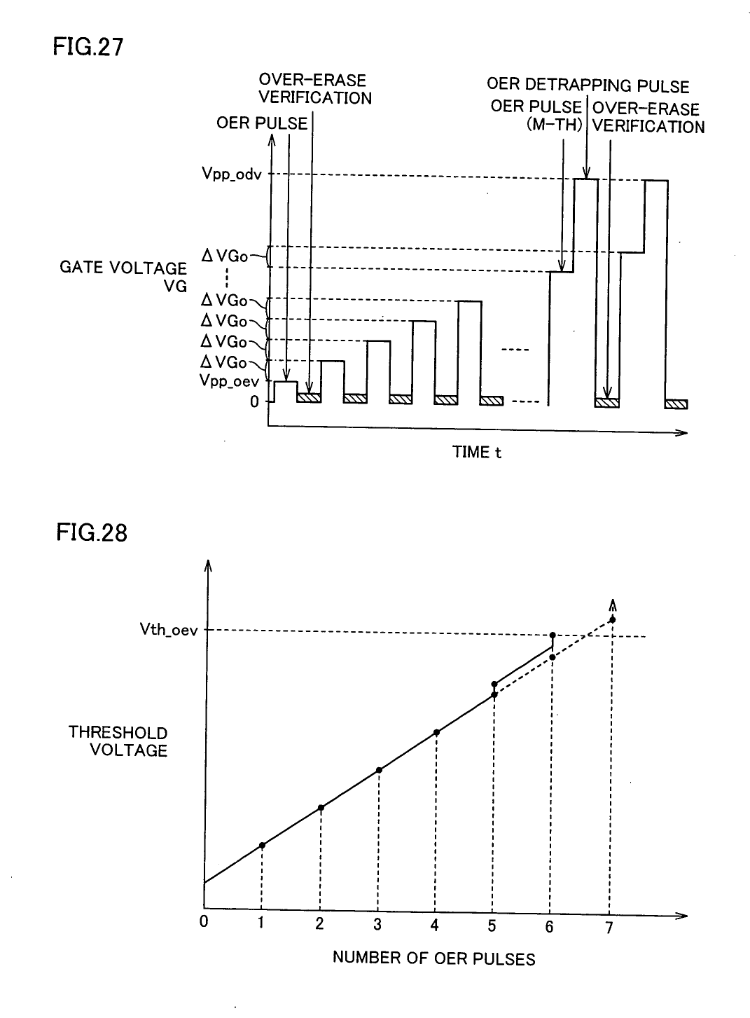

FIG. 27 is a time chart showing a temporal variation of gate voltage VG after the over-erase verification in the erase sequence shown in FIG. 26, which is to be compared with FIG. 16. FIG. 27 differs from FIG. 16 in that no OER detrapping pulse is applied until the number of OER pulses reaches M.

Thus, since application of the OER detrapping pulse to the memory cell can be prevented in the first half of the over-erase recovery operation in the erase sequence, in which deterioration of oxide film OM is considered to be relatively small, the operation time can be reduced.

FIG. 28 is a schematic diagram illustrating a state of variation of the threshold voltage of the memory cell after the over-erase verification in the erase sequence shown in FIG. 26, which is to be compared with FIG. 17. In this shown example, when the number of OER pulses is 5 or more, the OER detrapping pulse is applied. Then, in response to the application of the OER detrapping pulse following the sixth application of the OER pulse to the memory cell, the threshold voltage of the memory cell increases. In the following over-erase verification, it is determined that the lower limit value of the threshold voltage distribution of the memory cell has increased to over-erase verification reference value Vth_oev.

According to prior art, the OER detrapping pulse is not applied. Therefore, as shown by the dotted line, in the over-erase verification following the seventh application of the OER pulse to the memory cell, it is determined that the lower limit value of the threshold voltage distribution of the memory cell has increased to over-erase verification reference value Vth_oev, and then, the holes trapped in oxide film OM or near the oxide film interface are detrapped, and the threshold voltage of the memory cell decreases. That is, the threshold voltage of the memory cell changes after completion of the erase sequence, and thus, there is a problem that the read margin is reduced, and the operation reliability is reduced.

However, according to this embodiment 2, the over-erase verification is performed after the OER detrapping pulse is applied to the memory cell. In other words, the over-erase verification is performed after the holes trapped in oxide film OM or near the oxide film interface are detrapped. Therefore, a change of the threshold voltage of the memory cell after completion of the erase sequence can be avoided, an adequate read margin is ensured, and the operation reliability is improved.

For counting the number of program pulses or OER pulses, any pulse counter that has a memory function of temporarily storing the count for one write sequence or erase sequence can be used. The pulse counter is provided in control circuit 2 shown in FIG. 1.

Furthermore, instead of applying the PGM detrapping pulse or OER detrapping pulse to the memory cell, a WAIT operation of a predetermined period of time may be provided.

### Modification Example of Embodiment 2

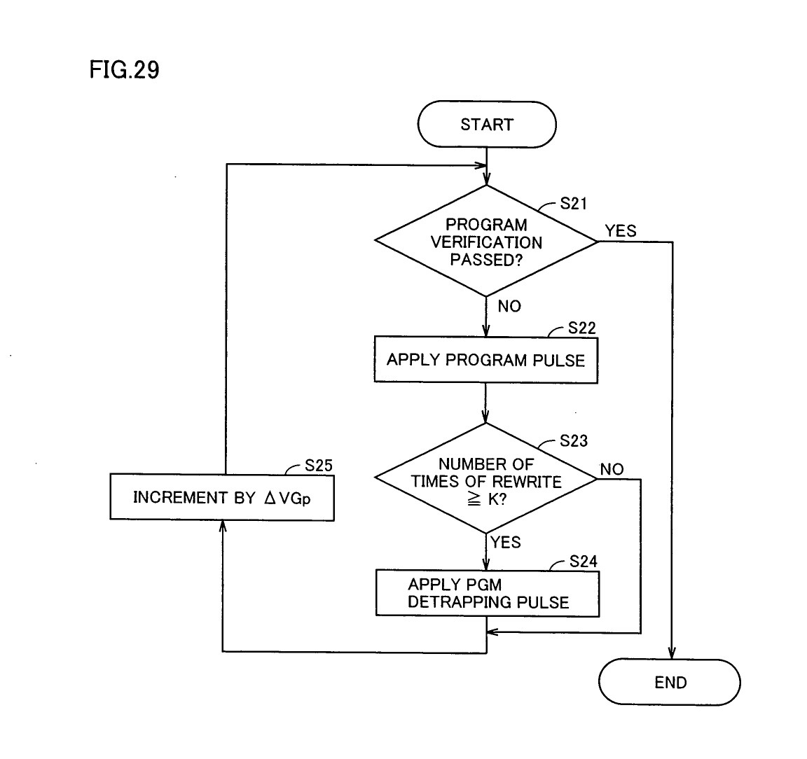

FIG. 29 is a flowchart showing an operation of a write sequence according to a modification example of the embodiment 2 of the present invention, which is to be compared with FIG. 23. FIG. 29 differs from FIG. 23 in that, in step S23, instead of counting the number of program pulses, the number of times of data rewrite of each memory cell, or in other words, the number of times of execution of the erase sequence and write sequence for each memory cell is counted.

In step S23, it is determined whether or not the number of times of data rewrite of a selected memory cell has reached a predetermined number K. If the number of times of data rewrite is less than K, the process proceeds to step S25 by skipping step S24, or if the number of times of data rewrite is equal to or more than K, the process proceeds to step S24.

Thus, at the stage when the number of times of data rewrite of the selected memory cell is small and it is considered that no deterioration of oxide film OM occurs, application of the PGM detrapping pulse to the memory cell can be avoided. Therefore, the operation time can be reduced.

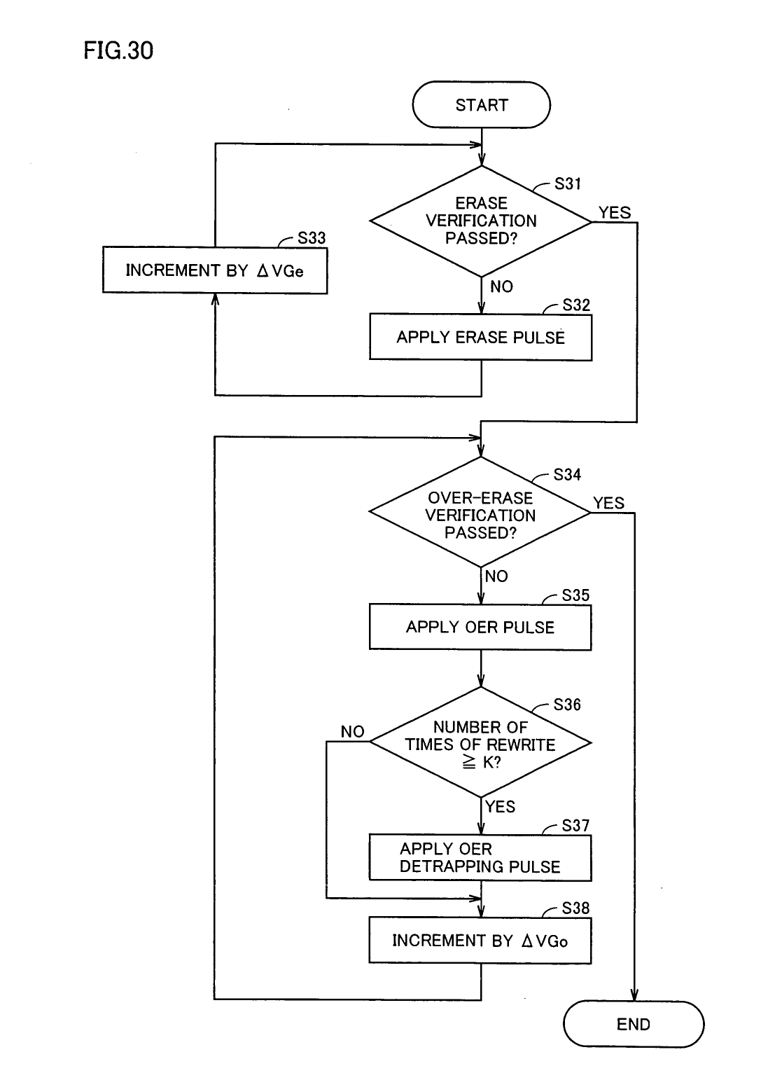

FIG. 30 is a flowchart showing an operation of an erase sequence according to the modification example of the embodiment 2 of the present invention, which is to be compared with FIG. 26. FIG. 30 differs from FIG. 26 in that, in step S36, instead of counting the number of OER pulse, the number of times of data rewrite of each memory cell, or in other words, the number of times of execution of the erase sequence and write sequence for each memory cell is counted.

In step S36, it is determined whether or not the number of times of data rewrite of a selected memory cell has reached a predetermined number K. If the number of times of data rewrite is less than K, the process proceeds to step S38 by skipping step S37, or if the number of times of data rewrite is equal to or more than K, the process proceeds to step S37.

Thus, at the stage when the number of times of data rewrite of the selected memory cell is small and it is considered that no deterioration of oxide film OM occurs, application of the OER detrapping pulse to the memory cell can be avoided. Therefore, the operation time can be reduced.

An erase/write counter for counting the number of times of data rewrite of each memory cell has a nonvolatile memory function of storing the count of the number of times of the erase sequence and write sequence performed on each memory cell and of retaining the content even after turn-off of the power supply, and sets a flag when the number of times of data rewrite reaches K. The erase/write counter may be provided in control circuit 2 shown in FIG. 1 or provided as a dedicated memory array outside control circuit 2.

Furthermore, instead of applying the PGM detrapping pulse or OER detrapping pulse to the memory cell, a WAIT operation of a predetermined period of time may be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A nonvolatile semiconductor memory device, comprising:
a memory array containing a plurality of memory cells arranged in a plurality of rows and columns, each memory cell having a floating gate and a control gate formed on a semiconductor substrate; and
a write/read/erase circuit that performs data writing/reading/erasing on a selected memory cell of said plurality of memory cells,
wherein said write/read/erase circuit writes data to said selected memory cell by injecting electrons from said semiconductor substrate into said floating gate via an oxide film,
applies a voltage lower than a voltage at said semiconductor substrate to said control gate, thereby detrapping charges trapped in said oxide film or near an interface between said oxide film and said semiconductor substrate during said data writing, and
performs a verification to check whether said selected memory cell is in a desired written state.

2. The nonvolatile semiconductor memory device according to claim 1, wherein said write/read/erase circuit further erases data in said selected memory cell by drawing electrons from said floating gate into said semiconductor substrate via said oxide film, and
the voltage applied to said control gate during said detrapping is smaller in absolute value than a voltage applied to said control gate during said data erasing.

3. The nonvolatile semiconductor memory device according to claim 1, wherein the source voltage and the drain voltage of said memory cell are equal to each other during said detrapping.

4. The nonvolatile semiconductor memory device according to claim 1, wherein said write/read/erase circuit counts the number of pulses of the voltage applied to said control gate of said selected memory cell during said data writing and performs said detrapping in the case where the number of counted pulses is equal to or more than a predetermined number.

5. The nonvolatile semiconductor memory device according to claim 1, wherein said write/read/erase circuit counts the number of times of data rewrite of each memory cell and performs said detrapping on a memory cell for which the count number is equal to or more than a predetermined number.

6. A nonvolatile semiconductor memory device, comprising:
a memory array containing a plurality of memory cells arranged in a plurality of rows and columns, each memory cell having a floating gate and a control gate formed on a semiconductor substrate; and
a write/read/erase circuit that performs data writing/reading/erasing on a selected memory cell of said plurality of memory cells,
wherein said write/read/erase circuit writes data to said selected memory cell by injecting electrons from said semiconductor substrate into said floating gate via an oxide film,
applies an equal voltage to said control gate and said semiconductor substrate for a predetermined period of time, thereby detrapping charges trapped in said oxide film or near an interface between said oxide film and said semiconductor substrate during said data writing, and
performs a verification to check whether said selected memory cell is in a desired written state.

7. The nonvolatile semiconductor memory device according to claim 6, wherein the source voltage and the drain voltage of said memory cell, the voltage applied to said control gate and the voltage applied to said semiconductor substrate are all set at 0 V during said detrapping.

8. The nonvolatile semiconductor memory device according to claim 6, wherein said write/read/erase circuit counts the number of pulses of the voltage applied to said control gate of said selected memory cell during said data writing and performs said detrapping in the case where the number of counted pulses is equal to or more than a predetermined number.

9. The nonvolatile semiconductor memory device according to claim 6, wherein said write/read/erase circuit counts the number of times of data rewrite of each memory cell and performs said detrapping on a memory cell for which the count number is equal to or more than a predetermined number.

10. A nonvolatile semiconductor memory device, comprising:
a memory array containing a plurality of memory cells arranged in a plurality of rows and columns, each memory cell having a floating gate and a control gate formed on a semiconductor substrate; and
a write/read/erase circuit that performs data writing/reading/erasing on a selected memory cell of said plurality of memory cells,
wherein said write/read/erase circuit erases data in said selected memory cell by drawing electrons from said floating gate into said semiconductor substrate via an oxide film,
performs an over-erase verification to check whether said selected memory cell is in an over-erased state because of said data erasing,
performs an over-erase recovery to write back data by injecting electrons into said floating gate from said semiconductor substrate via the oxide film if it is determined in said over-erase verification that the memory cell is in the over-erased state,
applies a voltage higher than a voltage at said semiconductor substrate to said control gate, thereby detrapping charges trapped in said oxide film or near an interface between said oxide film and said semiconductor substrate during said over-erase recovery, and
performs said over-erase verification again.

11. The nonvolatile semiconductor memory device according to claim 10, wherein the source voltage and the drain voltage of said memory cell is equal to each other during said detrapping.

12. The nonvolatile semiconductor memory device according to claim 10, wherein said write/read/erase circuit counts the number of pulses of the voltage applied to said control gate of said selected memory cell during said over-erase recovery and performs said detrapping in the case where the number of counted pulses is equal to or more than a predetermined number.

13. The nonvolatile semiconductor memory device according to claim 10, wherein said write/read/erase circuit counts the number of times of data rewrite of each memory cell and performs said detrapping on a memory cell for which the count number is equal to or more than a predetermined number.

14. A nonvolatile semiconductor memory device, comprising:
a memory array containing a plurality of memory cells arranged in a plurality of rows and columns, each memory cell having a floating gate and a control gate formed on a semiconductor substrate; and
a write/read/erase circuit that performs data writing/reading/erasing on a selected memory cell of said plurality of memory cells,
wherein said write/read/erase circuit erases data in said selected memory cell by drawing electrons from said floating gate into said semiconductor substrate via an oxide film,
performs an over-erase verification to check whether said selected memory cell is in an over-erased state because of said data erasing,
performs an over-erase recovery to write back data by injecting electrons into said floating gate from said semiconductor substrate via said oxide film if it is determined in said over-erase verification that the memory cell is in the over-erased state,
applies an equal voltage to said control gate and said semiconductor substrate for a predetermined period of time, thereby detrapping charges trapped in said oxide film or near an interface between said oxide film and said semiconductor substrate during said over-erase recovery, and
performs said over-erase verification again.

15. The nonvolatile semiconductor memory device according to claim 14, wherein the source voltage and the drain voltage of said memory cell, the voltage applied to said control gate and the voltage applied to said semiconductor substrate are all set at 0 V during said detrapping.

16. The nonvolatile semiconductor memory device according to claim 14, wherein said write/read/erase circuit counts the number of pulses of the voltage applied to said control gate of said selected memory cell during said over-erase recovery and performs said detrapping in the case where the number of counted pulses is equal to or more than a predetermined number.

17. The nonvolatile semiconductor memory device according to claim 14, wherein said write/read/erase circuit counts the number of times of data rewrite of each memory cell and performs said detrapping on a memory cell for which the count number is equal to or more than a predetermined number.
